(19) United States
(12) Patent Application Publication
(10) Pub. No.: US 2025/0042271 A1
(43) Pub. Date: Feb. 6, 2025

(54) DC VOLTAGE FAULT CURRENT MONITORING FOR DETECTING AN INSULATION FAULT

(71) Applicant: Vitesco Technologies GmbH, Regensburg (DE)

(72) Inventor: Franz Pfeilschifter, München (DE)

(21) Appl. No.: 18/560,829

(22) PCT Filed: May 23, 2022
(86) PCT No.: PCT/EP2022/063859

§ 371 Date: Jul. 2, 2024

(30) Foreign Application Priority Data
May 27, 2021 (DE) 10 2021 205 406.4

(51) Int. Cl. B60L 53/10; B60L 3/00; B60L 53/53; B60L 53/60; G01R 19/10; G01R 31/52

(52) U.S. Cl. CPC B60L 53/11; B60L 3/0069; B60L 53/53; B60L 53/60; G01R 19/10; G01R 31/52

(57) ABSTRACT

A monitoring circuit for a high-voltage DC charging apparatus provides for the monitoring circuit to have a first high-voltage busbar and a second high-voltage busbar as well as a reference potential. This is electrically insulated from the high-voltage busbars. The monitoring circuit has a current sensor apparatus which is configured to capture a common-mode current flowing through the high-voltage busbars. The monitoring circuit also has a control device. The current sensor apparatus has a signal-transmitting connection to the control device, and the control device is configured to emit a fault signal if the magnitude of the common-mode current exceeds a limit. Furthermore, a DC voltage charging station, a DC voltage charging cable, a vehicle charging circuit and a method for detecting a fault in a high-voltage DC charging process are described.

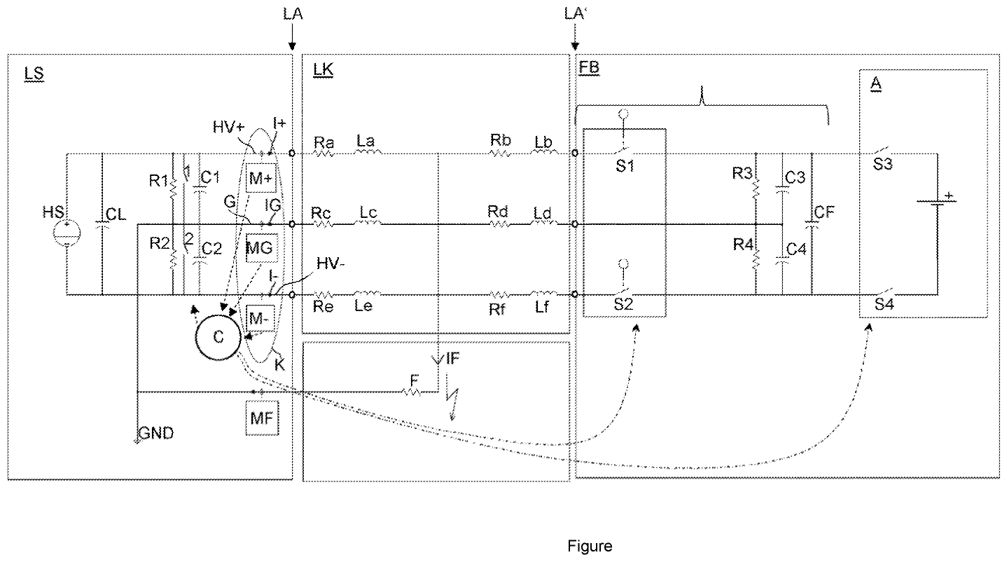

### CROSS REFERENCE TO RELATED APPLICATIONS

This application is the U.S. National Phase application of PCT International Application No. PCT/EP2022/063859, filed May 23, 2022, which claims priority to German Patent Application No. 10 2021 205 406.4, filed May 27, 2021, the contents of such applications being incorporated by reference herein.

### BACKGROUND OF THE INVENTION

For the operation of vehicles with an electrical drive, rechargeable batteries and drives with a high nominal voltage are used to enable high traction powers.

Correspondingly high voltages are used for charging, wherein the solutions described herein relate to charging by means of direct current, which does not require rectification of the electrical charging power.

The high voltages used for DC charging (typically greater than 200 V, for example in the range of 400-500 V or 800-850 V) are dangerous to humans, which is why the current in question is transmitted by means of two DC voltage potentials which are insulated with respect to a reference potential (chassis potential or ground potential).

Damage to the insulation can lead to insulation faults which can lead to dangerous contact currents for the user. In the field of DC charging, it is known to actively detect an insulation fault by using a test current to determine and evaluate the insulation resistance between a reference potential on the one hand and one of the high-voltage potentials on the other hand.

A corresponding approach is described in document DE 10 2018 217 574 A1, which is incorporated herein by reference. Typically, this determines the insulation resistance before the start of the DC charging process.

### SUMMARY OF THE INVENTION

An aspect of the invention aims to show a possibility that allows contact currents resulting from insulation faults to be captured during a DC charging process.

It is proposed to capture contact currents during DC voltage charging by determining a fault current, i.e. a difference in the currents carried by the high-voltage busbars. In a high-voltage DC charging apparatus, the charging power is transmitted via two high-voltage busbars (i.e. via two high-voltage potentials). If the first high-voltage busbar (for example the positive one) carries more current than is fed back via the second busbar, there must necessarily be an insulation fault, i.e. a current must flow away from the first high-voltage busbar and is not fed back via the second high-voltage busbar. This difference indicates the contact current in the event of an insulation fault that opens a contact current path. If the contact current or the difference exceeds a limit in terms of magnitude, a fault can be assumed.

The common-mode current is measured, i.e. the sum of the current in the first high-voltage busbar and the second high-voltage busbar (taking into account the opposite current directions). This sum is zero if the magnitudes of the currents in the busbars are the same, i.e. if the current intensity (incl. sign) of the current in the first busbar added to the current intensity (incl. sign) of the current in the second busbar is zero. In other words, in this context, the common-mode current corresponds to the difference in the magnitudes of the current intensities in the two busbars. If the deviation of the magnitudes is greater than a limit (which, for example, can correspond to a permissible contact current limit of a standard or a safety margin is below this), a fault signal is emitted. The fault signal signals or indicates a current that flows due to an insulation fault and that exceeds a limit, in particular a contact current that exceeds a (predefined) limit. The current sensor apparatus is preferably configured to capture the common-mode current of the two high-voltage busbars as a common common-mode current.

A conductor piece, such as wiring or a conductor track, is generally referred to as a busbar. The prefix “high-voltage” indicates a nominal voltage or maximum operating voltage of the component in question that is greater than 60 V, in particular at least 200 V, 400 V, 600 V or 800 V. This voltage specification refers to the voltage between the first and the second busbar in the case of busbars.

A monitoring circuit for a high-voltage DC charging apparatus is described. The charging apparatus itself is not part of the monitoring circuit. The term high-voltage DC charging apparatus should be generally understood and can relate to the source (charging station), the transmission path (charging cable, charging connection to converter, . . . ) and the sink (vehicle electrical system, vehicle charging circuit (i.e. in-vehicle charging circuit, in-vehicle rechargeable battery module, . . . ) of the charging power. The monitoring circuit can be provided in one or more of these system components (source, transmission path, sink).

The monitoring circuit has a first high-voltage busbar and a second high-voltage busbar. These busbars are electrically insulated from a reference potential or connection or busbar for the latter. The reference potential is also present in the monitoring circuit, especially since the charging power source, transmission path and sink are connected to a reference potential for safety reasons. The reference potential may be provided by a PE conductor or a ground potential, such as a charging station, or a vehicle chassis or vehicle ground potential of a vehicle, wherein the reference potential of the charging station with the vehicle connected is connected to the reference potential of the vehicle (or vehicle electrical system).

The monitoring circuit has a current sensor apparatus. This is configured to capture a common-mode current flowing through the high-voltage busbars. In this case, the current sensor apparatus may be designed to individually capture the currents flowing through the busbars and to form the sum (taking into account the different signs due to the opposite current flow directions). A current capturing element (such as a shunt resistor), through which the current of the relevant busbar flows, can be provided in each busbar. Furthermore, the current sensor apparatus may be designed to capture the common-mode current flowing through all of the busbars. In other words, the current sensor apparatus may be designed to capture the current difference in the currents flowing through the busbars (current magnitudes). For example, a magnetic core may be provided, which the busbars penetrate in the same direction, with the result that the magnetization of the magnetic core, taking into account the opposite current flow directions of the busbars, corresponds to the difference in the current magnitudes (and thus the sum of the busbar currents taking into account the different signs).

A control device is also provided and is configured to process the measurement signals emitted by the current sensor apparatus and to emit or not emit a fault signal depending on the common-mode current that is emitted from the current sensor apparatus to the control device. The current sensor apparatus has a signal-transmitting connection to the control device. As a result, the control device receives the measurement signal which reflects the common-mode current. The control device is configured to emit a fault signal if the magnitude of the common-mode current exceeds a limit. The fault signal reflects an impermissibly high contact current or fault current or common-mode current. The control device is configured, in particular, to not emit a fault signal (which reflects an excessively high common-mode current) if the magnitude of the common-mode current is not above the limit. The control device is thus configured to evaluate the signal from the current sensor apparatus and, if necessary, to emit a fault signal.

The control device may also be designed to condition the signal from the current sensor apparatus. A function of the current sensor apparatus may also be implemented in the control device, such as the formation of the sum (taking into account the signs) or the sum of the individually captured currents of the busbars. The current sensor apparatus and the control device can be at least partially integrated, for example in the form of a microprocessor with inputs which are connected to at least one current capturing element (or all current capturing elements).

One embodiment provides for the monitoring circuit to have a reference potential busbar. This carries the reference potential (PE conductor potential, ground potential, chassis or vehicle ground potential). The current sensor apparatus is configured in this embodiment to capture the common-mode current of all of the busbars (first, second high-voltage busbars and reference potential busbar). The current sensor apparatus is configured in this embodiment to capture the common-mode current of both high-voltage busbars and the reference potential busbar as a common common-mode current. If the current sensor apparatus has a magnetic core in order to use its magnetization to capture the common-mode current (by means of a magnet/Hall sensor) or its time derivative (by means of a sensor winding), both high-voltage busbars as well as the reference potential busbar run through the magnetic core.

The busbars preferably pass from the same side through the area that is spanned by the interior of the magnetic core. As a result, all currents through the busbars are added, taking into account the current direction (i.e. the signs of the currents). If all currents cancel each other, the common-mode current is zero and there is no fault current/contact current or the insulation fault described here does not exist. If the individual currents through the busbars do not cancel each other, a fault current flows away from a busbar (or is injected into it), and a fault current or contact current of greater than zero results.

When plugging in or connecting a DC voltage source or sink (or a transmission path) to the monitoring circuit, equalization and charging current flows occur, especially since said (real) system component has a parasitic capacitance and/or inductance, possibly also capacitances or inductances which are present as components, for example filter components. Equalization processes arise in the form of magnetization or charging processes of the inductances or capacitances that lead to a common-mode current through the two high-voltage busbars, which can lead to the erroneous triggering of the fault signal. If the common-mode current of the two high-voltage busbars and the reference-potential busbar is captured as a common common-mode current, the current flow resulting from the equalization processes during plugging-in passes through these three busbars in a mutually equalizing manner. If, for example, a capacitance is charged between a high-voltage busbar and the reference potential, this results in a common common-mode current of zero, since the current flows through the three busbars (both high-voltage busbars and the reference potential busbar) cancel each other. In particular, the current flow through the reference potential busbar compensates for the asymmetric charging current flow of the capacitances that exist between the high-voltage busbars and the reference potential. This is one of several possible ways of preventing equalization processes during plugging-in or connection from leading to erroneous triggering (i.e. emission of a fault signal). Further possibilities are described below.

The monitoring circuit may have a masking device which is configured to suppress the capture of a common-mode current (of the two high-voltage busbars or of these busbars together with the reference potential busbar) during a connection time interval. The connection time interval covers the time at which a charging current source is connected to the monitoring circuit. In other words, the connection time interval covers the time at which a DC voltage source or sink (or transmission path) is connected to the monitoring circuit. The connection time interval begins with the time of connection or with the occurrence of a signal indicating the connection (opening of the tailgate, plug-in signal from an interlock, closing command for a circuit breaker, etc.). The connection time interval can end after a predefined time period that reflects the duration of the equalization processes. The time interval can also be terminated if it is detected that the equalization processes have ended, for example if a voltage change rate falls below a limit value. This can apply to voltages that exist between the reference potential and one of the high-voltage busbars. The time interval can also be terminated if it is detected that the equalization processes have ended, for example if the magnitudes of equalization currents (charging/charge reversal currents) fall below a limit value.

Furthermore, since the equalization processes are often accompanied by oscillation processes (e.g. due to capacitances and inductances), the connection time interval can mark the time at which oscillations of the current (in one of the busbars) or of the voltage (between the reference potential and the high-voltage rail or between the high-voltage rails) occur. The masking device may also be configured to suppress common-mode currents having an overshoot (periodic pattern). Contact currents usually lead to aperiodic processes, with the result that they can be distinguished from equalization processes during connection processes on the basis of the signal properties. The masking device does not suppress the signals that can be associated with the aperiodic processes (aperiodic signals or common-mode currents) and suppresses signals that can be associated with oscillating processes (transient processes) (to be detected by aperiodically oscillating signals or common-mode currents). A corresponding masking device may be part of the monitoring circuit or the sensor apparatus, and may further be part of the control device. The masking device may be configured to suppress signals with a cosine component or signals with a non-monotonous profile and not to suppress monotonously rising or falling signals. The masking device may be configured to suppress or not suppress the emission of fault signals that trace back to said signals depending on these properties of the signals.

Alternatively, or in combination with this, the control device may therefore have a masking device, in particular a masking device having the above-mentioned properties and features. The masking device is preferably configured to suppress the emission of a fault signal during a connection time interval in which a charging current source is connected to the monitoring circuit. In this case, the connection time interval can be configured as described above. In this variant, the detection is not masked by suppressing the signal, but rather the emission of a fault is suppressed or the control device, which is configured to emit a fault signal, suppresses the emission of a fault signal in said situations or at said times.

The embodiment described below provides for not only a fault to be generally detected or a general fault signal to be emitted, but also allows a distinction to be made between which of the two high-voltage busbars are affected by the contact current (i.e. which of the two high-voltage busbars have an erroneously low insulation resistance with respect to the reference potential). The fault signal then indicates not only that a contact current/fault current that is above a limit flows, but also which of the two high-voltage potentials or high-voltage busbars are affected by this. The polarity of the common-mode current indicates the polarity of the high-voltage busbar or the high-voltage potential which is affected due to faulty insulation with respect to the reference potential for the contact current or by the insulation fault. The control device may be designed for this purpose. The control device is preferably configured to emit a first type of fault signal if the magnitude of the common-mode current exceeds the limit and the common-mode current has a first polarity. The control device is configured, in particular, to emit a second type of fault signal if the magnitude of the common-mode current exceeds the limit and the common-mode current has a polarity opposite the first polarity. The type of fault signal preferably indicates the polarity of the high-voltage potential which is connected to the reference potential via an excessively low insulation resistance, i.e. from which the contact current is emitted or into which the contact current is injected.

A first and a second discharge switch may be provided, wherein the first discharge switch is provided between the reference potential and the first high-voltage busbar and the second discharge switch is provided between the reference potential and the first high-voltage busbar. The control device is preferably connected to the discharge switches in a controlling manner. The control device is preferably configured to close that discharge switch which is connected to that high-voltage busbar which has the same polarity as the common-mode current. The other discharge switch preferably remains open. The control device is configured, in particular, to close the first or the second discharge switch depending on the type of fault signal or depending on the polarity of the common-mode current. The other discharge switch in each case preferably remains open. The control device is designed accordingly.

The first high-voltage busbar preferably has the first polarity which is positive, for example. In particular, the first high-voltage busbar has a first high-voltage potential which is positive, for example. The second high-voltage busbar may have the second (opposite) polarity which is negative, for example. In particular, the second high-voltage busbar has a second high-voltage potential which is negative, for example. The first type of fault signal preferably indicates a contact current on the first (positive) high-voltage busbar. The second type of fault signal indicates a contact current on the second high-voltage busbar. The first type of fault signal differs from the second type of fault signal. The fault signal can be binary and is designed in particular according to a (vehicle-related) standard for data transmission. The control device is preferably configured, in the event of a first type of fault signal, to close a discharge switch which connects the first high-voltage busbar to the reference potential (or the reference potential busbar) in a switchable manner, in particular via a discharge resistor. The control device is configured, in particular, in the event of a second type of fault signal, to close a discharge switch which connects the second high-voltage busbar to the reference potential (or the reference potential busbar) in a switchable manner, in particular via a discharge resistor. During the closed state of the relevant discharge switch, the other discharge switch in each case remains open; the control device is designed accordingly to control this. The control device is designed to emit a control signal for the corresponding discharge switches which initiates the aforementioned control.

One embodiment provides for the control device to be configured to emit a fault signal, which indicates a contact current on the positive high-voltage busbar, if the magnitude of the common-mode current exceeds the limit and the common-mode current is positive. The control device may be configured to emit a fault signal, which indicates a contact current on the negative high-voltage busbar, if the magnitude of the common-mode current exceeds the limit and the common-mode current is negative. Another embodiment provides for the control device to be configured to emit a fault signal, which indicates a contact current on the positive high-voltage busbar, if the common-mode current exceeds a positive limit. The control device may be configured to emit a fault signal, which indicates a contact current on the negative high-voltage busbar, if the common-mode current falls below a negative limit.

The current sensor apparatus can be based on shunt resistors that can be used to determine the common-mode current. Furthermore, the current sensor apparatus may be based on the detection of a static magnetic field (caused by the common-mode current) or on the detection of a variable magnetic field (caused by the change in the common-mode current). In the detection by means of a magnetic field, use is preferably made of a magnetic core which collects the magnetic fields of the relevant busbars. The current sensor apparatus may therefore have a magnetic core that encompasses the busbars. The magnetic core can carry a sensor winding. If the magnetic field or the magnetization in the magnetic core changes, this induces a voltage in the sensor winding. This reflects the common-mode current (in particular its temporal change). In addition, the magnetic core may be magnetically coupled to a Hall sensor. The Hall sensor may be provided in an air gap of the magnetic core in order to thus detect the magnetization or the magnetic field in the magnetic core. The signal from the Hall sensor reflects the magnetic flux strength and thus the intensity of the common-mode current. Alternatively, the current sensor apparatus may have a shunt resistor. Preferably, a shunt resistor is provided (in series) in each of the busbars. The sum of all voltages dropped across the shunt resistors reflects the common-mode current flowing through the busbars. This applies to the first and the second high-voltage busbar as well as the reference potential busbar, if appropriate. The determination of the common-mode current, and in particular the sensor apparatus, refers to the common-mode current of the first and the second high-voltage busbar as well as the reference potential busbar, if appropriate.

The monitoring circuit can be used in one or more of the system components mentioned (source, transmission path, sink). An application in a source in the form of a charging station for plug-in electric vehicles is described below. A DC voltage charging station is designed with the monitoring circuit described here. The DC voltage charging station has a charging connection, upstream of which the monitoring circuit is connected. The charging connection is designed in such a way that a charging cable can be inserted (from the outside). The charging connection is preferably designed according to a standard for charging electric vehicles. The monitoring circuit is preferably connected directly upstream of the charging connection, i.e. in particular without interposed filter components or converters. The charging station has circuit breakers which are controlled by the monitoring circuit (directly or indirectly via a further data processing unit) and which are opened directly or indirectly by the monitoring circuit if the fault signal occurs. In this case, only one circuit breaker of one busbar of only one polarity can be opened, especially if the fault signal of the relevant type (which also refers to this polarity) occurs.

An application in a transmission path in the form of a DC voltage charging cable for plug-in electric vehicles is described below. The charging cable can also have the monitoring circuit. The busbars of the monitoring circuit are interposed in series between opposite ends of the charging cable. One end of the charging cable or both ends of the charging cables has/have a plug-in connecting element which is preferably designed according to a standard for charging electric vehicles.

An application in a sink in the form of a vehicle charging circuit for plug-in electric vehicles is described below. The vehicle charging circuit is designed for charging with direct current or is a DC voltage vehicle charging circuit. The vehicle charging circuit has a charging connection, downstream of which the monitoring circuit is connected. This charging connection is preferably designed according to a standard for charging electric vehicles. The monitoring circuit is preferably connected directly downstream of this charging connection, i.e. in particular without interposed filter components or converters. The vehicle charging circuit has circuit breakers which are controlled by the monitoring circuit (directly or indirectly via a further data processing unit) and which are opened directly or indirectly by the monitoring circuit if the fault signal occurs. In this case, only one circuit breaker of one busbar of only one polarity can be opened, especially if the fault signal of the relevant type (which also refers to this polarity) occurs.

A method for detecting a fault in a high-voltage DC charging process, in particular an insulation fault of a high-voltage potential with respect to a reference potential, is also described. The method implements the procedure described here and therefore has features that correspond to the properties of apparatus features described here.

As part of the method, a first high-voltage potential and a second high-voltage potential are transmitted via a first and a second high-voltage busbar. A charging power is transmitted by means of a direct current which is carried via the high-voltage busbars. The method provides for a common-mode current flowing through the busbars to be captured, preferably with the means described here. The common-mode current is compared with a limit; in particular, the magnitude of the common-mode current is compared with the limit. This can happen in the control device. A fault signal is emitted if the common-mode current is positive and exceeds an upper limit, or if the common-mode current is negative and falls below a lower limit. Different types of fault signals can be emitted in this case, depending on whether the upper limit is exceeded or the lower limit is undershot. Alternatively, a fault signal is emitted if the magnitude of the common-mode current exceeds a limit. Circuit breakers that are configured to disconnect the power path of the charging power can be opened if such a fault signal is emitted.

A first type of fault signal can be emitted if the common-mode current is positive and exceeds the upper limit (or the magnitude of the common-mode current exceeds a limit). A second type of fault signal can be emitted if the common-mode current is negative and falls below the lower limit (or the magnitude of the common-mode current exceeds a limit). Instead of or in combination with the emission of first or second type of fault signals, provision can be made, in the case of a positive common-mode current (above the limit), for the positive high-voltage potential rail to be discharged in relation to a reference potential such as ground or chassis, and, in the case of a negative common-mode current (above the limit or below a negative limit in terms of magnitude), for the negative high-voltage potential rail to be discharged in relation to a reference potential such as ground or chassis. Preferably only one high-voltage potential rail is discharged in relation to the reference potential at a time, not both at the same time.

### BRIEF DESCRIPTION OF THE DRAWINGS

The FIGURE is used to provide an exemplary explanation of the apparatuses described here and the method described here.

### DETAILED DESCRIPTION OF THE PREFERRED EMBODIMENTS

A (DC) charging station LS is connected to a (DC) charging cable LK via a charging connection LA of the charging station LS. The charging cable LK connects the charging connection LA of the charging station LS to a charging connection LA′ of a (DC) vehicle electrical system FB. Line resistances Ra-Rf which are assigned to the charging cable are illustrated. Inductances (of the parasitic type) La-Lf which are also assigned to the charging cable are also illustrated. The elements Ra-Rf and La-Lf relate to an equivalent circuit diagram of the charging cable LK.

The vehicle electrical system FB has a rechargeable battery apparatus A which has the rechargeable battery and circuit breakers S3, S4. The rechargeable battery apparatus A is connected via circuit breakers S1, S2 to the charging connection LA′ of the vehicle electrical system FB, in particular without converters. There is an intermediate circuit capacitance CF between the rechargeable battery apparatus A and the circuit breakers S1, S2. Parasitic or filter-based Cy capacitors C3, C4 and insulation resistances R3, R4 (as components of an equivalent circuit diagram) are illustrated.

The equivalent circuit diagram components C3, C4 and R3, R4 each connect a reference potential GND to a high-voltage potential. A first high-voltage potential HV+ and a second high-voltage potential HV− are illustrated. Due to the connection between the charging station, charging cable and vehicle electrical system, all three of these system components have these high-voltage potentials. This also applies to the reference potential GND.

The charging station LS has a DC voltage source HS which outputs the high-voltage potentials HV+, HV−. Two high-voltage busbars, which carry these high-voltage potentials HV+, HV− and are therefore denoted using the same reference signs, are illustrated. The charging station LS has insulation resistances R1, R2 which have the reference potential GND of the relevant busbar G in relation to the high-voltage potentials HV+, HV−. In addition, corresponding capacitances C1, C2 are illustrated as Cy capacitances. These correspond to components of an equivalent circuit diagram of lines within the charging station. An intermediate circuit capacitor CL of the charging station LS is connected to the potentials HV+, HV− of the charging station LS. The charging station LS has a monitoring circuit that has two high-voltage busbars HV+, HV−. These can be considered to be a section of the high-voltage busbars of the charging station LS. In addition, the monitoring circuit has a reference potential busbar G which carries the reference potential GND (ground potential). A current sensor apparatus is configured to capture the currents I+, I− and IG that flow through the busbars. More precisely, the current sensor apparatus is configured to capture the common-mode current (sum of the currents IG, I− and I+) of the busbars HV+, G, HV−. The capture of the individual currents by means of the measurement devices M+, M− and M− is illustrated symbolically. Preferably, use is made of a current sensor apparatus which captures the common-mode current. It is also possible to provide individual sensor measurement elements, as illustrated with M+, M− and MG, which capture the individual currents I+, I− and IG, with the result that they (incl. sign) can be added, for example by a control device C.

It is possible to provide a magnetic core K which encompasses the busbars HV+, HV− and G and which is magnetized by their common-mode current. A magnet sensor or a sensor coil can be magnetically coupled to the magnetic core and can thus capture the common-mode current (via the strength of the magnetization or the magnetic flux through the core or the time derivative of these variables). The relevant captured signal, which reflects the common-mode current, is transmitted to the control device C.

The control device C emits a signal if the common-mode current (its magnitude or the magnitude of the time derivative thereof) exceeds a limit. The limit may be predefined by storage in a memory of the control device C or by entry via an input of the control device. The control device is configured, in particular, to distinguish a negative common-mode current or a negative first time derivative of the common-mode current from a positive common-mode current or a positive first time derivative of the common-mode current and to emit different types of fault signals if the limit is exceeded/undershot. This allows the fault signal to be used to determine which high-voltage potential is affected by the insulation fault with respect to the reference potential.

The method of operation is described below: If there is an insulation fault resistance F, i.e. a resistance that connects a high-voltage potential of a busbar HV+ (of the charging station LS or the charging cable LK connected to it) to the reference potential GND due to an insulation fault, a fault current IF flows. In this case, a person, for example, can represent the resistance. A part IF of the current I+, which is output by the charging station LS, thus flows directly to the potential GND (via resistance F), with the result that only a part of the current I+, which is output by the charging station LS, reaches the vehicle electrical system FB. Consequently, the magnitude of the return current I− is lower, namely by the amount that constitutes IF. Therefore, the magnitude of the return current I− arriving at the charging station is less than the magnitude of the current I+ output by the charging station. The result is a positive common-mode current for the busbars HV+, HV− and G, which is captured. In this case, it is preferable to determine not only whether the magnitude of the common-mode current is above a limit, but also which sign it has. If the sign is positive, there is, as illustrated, an insulation fault in the positive potential rail (one of the components LK, FB that are connected downstream of the monitoring circuit or the charging station LS) in the form of the resistance F which enables the fault current IF.

When connecting the charging station to the charging cable LK or to the vehicle electrical system FB (plugging into connections LA, LA′ or closing the switches S1, S2 or S3, S4), a charge equalization current is produced, especially if the Cy capacitors C3, C4 of the vehicle electrical system FB are still uncharged or if the inductances La-Lf are not magnetized. In this case, an asymmetric equalization process (with respect to the reference potential GND) will arise, in which the charge equalization current flows. The charging of the capacitance CF of the vehicle electrical system FB also generates a current surge. During plugging-in, these processes thus lead to currents which (also) entail a common-mode current component. These can be suppressed by a masking device.

In addition, however, as illustrated, not only the high-voltage busbars HV+, HV−, but also the reference potential busbar G, can be used to capture the common-mode current. Thus, the common-mode current of the individual currents flowing through the high-voltage busbars HV+, HV− and through the reference potential busbar G is determined. However, asymmetric components of the currents, which are produced by equalization processes during plugging-in/connection, are discharged via the reference potential busbar G to the potential GND, with the result that charging processes/magnetization processes beyond the monitoring apparatus MF (i.e. beyond the point at which the currents of the busbars are measured) overall do not lead to a common-mode current. In other words, the consideration of the current through the reference potential busbar when capturing the common-mode current compensates for asymmetries in the equalization processes that arise during plugging-in. If, as illustrated symbolically, the current IG is also captured in addition to the currents I+ and I− in order to form the common common-mode current, then equalization processes do not lead to the generation of a fault signal, since asymmetric equalization current components are equalized by also taking the current IG (current of the reference potential busbar) into account when forming the common-mode current.

The control device C can be connected to circuit breakers S1, S2 or S3, S4 in a controlling manner. If it is determined that the magnitude of the common-mode current is above a limit, then the control device C controls the circuit breakers to open. The control device C is designed for this purpose. The switches S1, S2 form an all-pole circuit breaker apparatus connected upstream of the charging connection LA′ of the vehicle electrical system FB. The switches S3, S4 form an all-pole circuit breaker apparatus within the rechargeable battery apparatus A, which, when open, disconnect the rechargeable battery from connections of the rechargeable battery apparatus A.

In certain embodiments, a first discharge switch 1 and a second discharge switch 2 may be provided. Discharge switch 1 connects the high-voltage busbar HV+ to the reference potential busbar G in a switchable manner. Discharge switch 2 connects the high-voltage busbar HV− to the reference potential busbar G in a switchable manner. The discharge switches 1, 2 are preferably part of the monitoring circuit. The control device C is connected to the discharge switches 1, 2 in a controlling manner. The control device C is configured to close one of the two discharge switches 1, 2 (while the other remains open) when the fault described here is detected. The control device C is configured to close one of the two discharge switches 1, 2 (while the other remains open) if the magnitude of the common-mode current exceeds a limit.

If the common-mode current (sum of I+, IG, I− or |+ and I−) is positive, this corresponds to a fault current that affects the high-voltage busbar HV+. This corresponds to a fault state that triggers the first type of fault signal. The control device C is configured in this case to close that discharge switch which is connected to the first high-voltage busbar HV+, i.e. discharge switch 1. If the common-mode current is negative, this corresponds to a fault current that affects the second high-voltage busbar HV−. This corresponds to a fault state that triggers the second type of fault signal. The control device C is configured in this case to close that discharge switch which is connected to the second high-voltage busbar HV−, i.e. discharge switch 2. The control device C is configured in particular to close the first or the second discharge switch 1, 2, depending on the type of fault signal. In the event of a first type of fault signal, the first discharge switch 1 is closed (not the second). In the event of a second type of fault signal, the second discharge switch 2 is closed (not the first). The control device C is designed and connected to the discharge switches 1, 2 in a controlling manner in order to carry out this control and to make the relevant distinction based on the polarity of the common-mode current. Discharge switches 1, 2, which connect the busbar G directly to the busbar HV+, HV− are illustrated symbolically. However, it also possible to provide discharge resistors which are connected in series with the discharge switches, wherein each discharge switch is not connected directly, but via one of the discharge resistors (current limiting resistor), to the relevant busbars, in particular in order to limit the discharge current.

The limit with which the magnitude of the common-mode current is compared is preferably between 1 and 40 mA, preferably 30 mA or less, 20 mA or less, 10 mA or less, 5 mA or less, or 3.5 mA or less.

Furthermore, provision may be made for the fault signal to be emitted only if the common-mode current exceeds (or falls below) the limit for longer than a predefined time period (for instance longer than 1 ns, 10 ns, 100 ns, 1 ms or longer than 5 ms). The time period can increase with the amount by which the magnitude of the common-mode current exceeds the limit.

1. A monitoring circuit for a high-voltage DC charging apparatus, wherein the monitoring circuit has a first high-voltage busbar and a second high-voltage busbar and having a reference potential electrically insulated from the high-voltage busbars, wherein the monitoring circuit
has a current sensor apparatus which is configured to capture a common-mode current flowing through the high-voltage busbars, and
has a control device, wherein the current sensor apparatus has a signal-transmitting connection to the control device, and the control device is configured to emit a fault signal if the magnitude of the common-mode current exceeds a limit.

2. The monitoring circuit as claimed in claim 1, wherein the monitoring circuit has a reference potential busbar, and the current sensor apparatus is configured to capture a common-mode current flowing through the high-voltage busbars and through the reference potential busbar.

3. The monitoring circuit as claimed in claim 1, wherein the monitoring circuit has a masking device which is configured to suppress the capture of a common-mode current during a connection time interval in which a charging current source is connected to the monitoring circuit, and/or wherein the control device has a masking device which is configured to suppress the emission of a fault signal during a connection time interval in which a charging current source is connected to the monitoring circuit.

4. The monitoring circuit as claimed in claim 1, wherein
the control device is configured to emit a first type of fault signal if the magnitude of the common-mode current exceeds the limit and the common-mode current has a first polarity, and to emit a second type of fault signal if the magnitude of the common-mode current exceeds the limit and the common-mode current has a polarity opposite the first polarity, wherein the control device is configured, in particular, to close a first discharge switch between the first high-voltage potential rail and the reference potential rail in the event of a first type of fault signal, and to close a second discharge switch between the second high-voltage potential rail and the reference potential rail in the event of a second type of fault signal.

5. The monitoring circuit as claimed in claim 4, wherein the first high-voltage busbar has the first polarity and the second high-voltage busbar has the second polarity, and the first type of fault signal indicates a contact current on the first high-voltage busbar, and the second type of fault signal indicates a contact current on the second high-voltage busbar.

6. The monitoring circuit as claimed in claim 1, wherein
the current sensor apparatus has a magnetic core which encompasses the busbars and which carries a sensor winding or which is magnetically coupled to a Hall sensor, or wherein
the current sensor apparatus has a shunt resistor.

7. A DC voltage charging station having the monitoring circuit as claimed in claim 1, wherein the DC voltage charging station further has a charging connection, upstream of which the monitoring circuit is connected.

8. A DC voltage charging cable having the monitoring circuit as claimed in claim 1, wherein the busbars of the monitoring circuit are interposed in series between opposite ends of the charging cable.

9. A vehicle charging circuit having the monitoring circuit as claimed in claim 1, wherein the vehicle charging circuit further comprises a charging connection, downstream of which the monitoring circuit is connected.

10. A method for detecting a fault in a high-voltage DC charging process, wherein a first high-voltage potential and a second high-voltage potential are transmitted via a first and a second high-voltage busbar, of the method comprising:
capturing a common-mode current flowing through the busbars;
comparing the common-mode current with a limit; and
emitting a fault signal if the common-mode current is positive and exceeds an upper limit, or if the common-mode current is negative and falls below a lower limit.

11. The method as claimed in claim 10, wherein a first type of fault signal is emitted if the common-mode current is positive and exceeds the upper limit, and a second type of fault signal is emitted if the common-mode current is negative and falls below the lower limit.

12. The monitoring circuit as claimed in claim 2, wherein the monitoring circuit has a masking device which is configured to suppress the capture of a common-mode current during a connection time interval in which a charging current source is connected to the monitoring circuit, and/or wherein the control device has a masking device which is configured to suppress the emission of a fault signal during a connection time interval in which a charging current source is connected to the monitoring circuit.
